(19) United States
(12) Patent Application Publication
(10) Pub. No.: US 2026/0182203 A1
(43) Pub. Date: Jun. 25, 2026

(54) DISPLAY PANEL

(71) Applicant: LG Display Co., Ltd., Seoul (KR)

(72) Inventor: Heejin KIM, Paju-si (KR)

(73) Assignee: LG Display Co., Ltd., Seoul (KR)

(21) Appl. No.: 19/333,848

(22) Filed: Sep. 19, 2025

(30) Foreign Application Priority Data
Dec. 23, 2024 (KR) 10-2024-0193949

(51) Int. Cl. H10K 59/80; H10K 59/122

(52) U.S. Cl. CPC H10K 59/80518; H10K 59/122; H10K 59/876

(57) ABSTRACT

Disclosed is a display panel in which an individual light-emitting element layer is disposed on each of at least one first electrode, and a common light-emitting element layer is additionally disposed so as to cover the individual light-emitting element layers across multiple sub pixels. By providing both the individual light emitting element layer and the common light emitting element layer in this manner, reflection efficiency in a specific sub-pixel can be increased, resulting in improved luminance in that sub-pixel. The configuration allows optical path length and emission characteristics to be selectively adjusted for targeted sub pixels while maintaining overall panel structure, thereby achieving enhanced performance without unnecessary increases in thickness or complexity.

### CROSS REFERENCE TO RELATED APPLICATION

The present application claims priority to Korean Patent Application No. 10-2024-0193949, filed Dec. 23, 2024, the entire contents of which is incorporated herein for all purposes by this reference.

### BACKGROUND

### Technical Field

The present disclosure relates to a display panel capable of improving luminance.

### Description of the Related Art

Display devices are implemented in a wide variety of forms, such as televisions, monitors, smartphones, tablet PC, laptops, wearable devices, etc.

An organic light-emitting display device (OLED) among display devices displaying various information as an image is a self-luminous device that emits light by itself, and has advantages in that a response speed is fast, light emission efficiency and luminance are high and a viewing angle is large, and a contrast ratio and color gamut are excellent.

Recently, as users'demands for high-quality images increase, development of high-resolution display devices is actively progressing.

### BRIEF SUMMARY

Recently, a head-mounted display device (HMD) including an organic light-emitting display device has been developed. When a user wears the HMD on his or her head, the HMD displays a display screen in front of his or her eyes. The head-mounted display device is used in various applications such as Virtual Reality (VR), Augmented Reality (AR), Mixed Reality (MR), and the like, and may play an important role in providing an immersive experience to the user.

In an example, the display device may be formed using an organic light-emitting diode on silicon (OLEDoS) technique as a technique of forming a OLED on a silicon substrate. In general, the OLEDoS technique may be used to manufacture a display device having higher resolution and higher density using a silicon wafer instead of a glass or plastic substrate.

Applying a microcavity structure to the display device having such a OLEDoS structure may help improve the efficiency of the display device and improve color gamut. The microcavity structure may increase color gamut by amplifying light of a specific wavelength in an organic light-emitting display device. The microcavity structure is composed of a thin dielectric layer and a reflective layer, and may amplify the emission efficiency of light in the OLED structure by resonating and strengthening light of a specific wavelength. In one example, the display device having the OLEDoS structure may control the light emission wavelength of each sub-pixel using change in a thickness of an insulating layer as a dielectric layer disposed under the white organic light-emitting element (WOLED).

That is, in the display device having the OLEDoS structure, an optical resonance distance is formed using the dielectric layer positioned between the reflective layer and the anode electrode. Thus, luminous efficiency and color gamut may be improved. In this case, the dielectric layer directly affects the optical properties of the light-emitting element, and thus may serve to adjust the light emission efficiency in a specific wavelength region. However, following problems may exist in the display device having such a OLEDoS structure.

First, the dielectric layer causes change in light reflection characteristics according to its thickness or refractive index. This may directly affect the light extraction efficiency of the sub-pixel. For example, in a green sub-pixel, reflectance is lowered to about 70% due to the dielectric layer. Such a decrease in the reflectance in the specific sub-pixel may prevent light emitted from the light emission layer from being effectively extracted to a front surface, and thus, the light emission efficiency of the light-emitting element may be greatly reduced, and in the end, the total luminance performance of the display panel may be reduced.

In addition, when the luminous efficiency of the display panel is lowered as described above, a larger current should flow to obtain the same level luminance. The increase in the current density may accelerate thermal or chemical deterioration of a material inside the light-emitting element including the light-emitting layer. This may shorten the light-emitting element life and lead to deterioration of the display panel characteristics during long-term use. In particular, in environments that require long-term operation and high-quality implementation, such as the virtual reality devices or augmented reality devices, such lifespan and reliability problems may cause serious quality degradation.

In addition, the virtual reality devices or augmented reality devices require ultra-high resolution, high luminance, high color gamut, and wide viewing angle. However, in the OLEDoS structure, the dielectric layer reduces the efficiency, and thus it may be difficult to implement high luminance. In addition, when the current density is increased without an alternative to improving the efficiency, the problem of lowering the lifespan may become more prominent. Therefore, there is a need for a display panel capable of achieving the best performance level such as high pixel density, long-term stability, excellent contrast ratio, etc., required by the virtual reality device or the augmented reality device.

Accordingly, the present disclosure provides a display panel configured to improve luminance, the structure and features of which have been developed based on various experiments.

Various embodiments of the present disclosure provide a display panel capable of improving reflection efficiency and luminance in a specific sub-pixel.

Various embodiments of the present disclosure provide a display panel capable of securing optimal reflectance and luminous efficiency in each sub-pixel.

Various embodiments of the present disclosure provide a display panel capable of increasing light extraction efficiency and luminance.

Various embodiments of the present disclosure provide a display panel capable of suppressing an increase in thickness by efficiently managing the thickness of the display panel.

Various embodiments of the present disclosure provide a display panel capable of achieving balance of red, green, and blue light emissions and high-quality image implementation.

Various embodiments of the present disclosure provide a display panel that may be advantageous for implementing an ultra-high resolution panel for a display device such as a virtual reality device or an augmented reality device.

Various embodiments of the present disclosure provide a display panel capable of preventing deterioration of a light-emitting material of a light-emitting layer and extending the light-emitting element lifespan.

Technical benefits according to the present disclosure are not limited to the above-mentioned benefits. Other benefits and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

One aspect of the present disclosure provides a display panel comprising: a substrate including first to third sub-pixel areas corresponding to first to third sub-pixels; a reflective electrode disposed in each of the first sub-pixel, the second sub-pixel, and the third sub-pixel; a first electrode individually disposed on each of the reflective electrodes and individually disposed in each of the first sub-pixel, the second sub-pixel, and the third sub-pixel; an individual light-emitting element layer individually disposed on each of at least one of the first electrodes respectively disposed in the first sub-pixel, the second sub-pixel, and the third sub-pixel; a common light-emitting element layer disposed on the individual light-emitting element layer and disposed in the first sub-pixel, the second sub-pixel, and the third sub-pixel; and a second electrode disposed on the common light-emitting element layer and disposed in the first sub-pixel, the second sub-pixel, and the third sub-pixel.

In accordance with some embodiments of the display panel, the individual light-emitting element layer includes a first individual light-emitting element layer, a second individual light-emitting element layer, and a third individual light-emitting element layer respectively disposed in the first sub-pixel, the second sub-pixel, and the third sub-pixel, wherein the first individual light-emitting element layer, the second individual light-emitting element layer, and the third individual light-emitting element layer have different vertical heights.

In accordance with some embodiments of the display panel, the vertical height of the first individual light-emitting layer is greater than the vertical height of each of the second individual light-emitting layer and the third individual light-emitting layer, wherein the vertical height of the second individual light-emitting layer is greater than the vertical height of the third individual light-emitting layer.

In accordance with some embodiments of the display panel, the display panel further comprises a first insulating layer disposed between the reflective electrode of the third sub-pixel and the substrate, wherein the first insulating layer is disposed between the reflective electrode and the first electrode in the second sub-pixel, and is absent in the first sub-pixel.

In accordance with some embodiments of the display panel, a distance between the reflective electrode and the second electrode in the third sub-pixel is smaller than each of a distance between the reflective electrode and the second electrode in the first sub-pixel and a distance between the reflective electrode and the second electrode in the second sub-pixel.

In accordance with some embodiments of the display panel, the reflective electrode and the first electrode in the first sub-pixel contact each other, wherein the reflective electrode and the first electrode in the third sub-pixel are in contact with each other, wherein a first insulating layer is disposed between the reflective electrode and the first electrode in the second sub-pixel.

In accordance with some embodiments of the display panel, the display panel further comprises: a first bank layer having a first patterned area defined therein, wherein the first individual light-emitting element layer is disposed in the first patterned area; a second bank layer having a second patterned area defined therein, wherein the second individual light-emitting element layer is disposed in the second patterned area; and a third bank layer having a third patterned area defined therein, wherein the third individual light-emitting element layer is disposed in the third patterned area, wherein a depth of the first patterned area is greater than each of a depth of the second patterned area and a depth of the third patterned area.

In accordance with some embodiments of the display panel, the display panel further comprises a first insulating layer disposed under the second bank layer and the third bank layer, wherein the first bank layer and the first insulating layer are disposed in the same layer.

In accordance with some embodiments of the display panel, the individual light-emitting element layer includes a third individual light-emitting element layer disposed in the third sub-pixel, wherein a first insulating layer is disposed between the first electrode in each of the first to third sub-pixels and the substrate, wherein a second insulating layer is disposed between the first electrode and the first insulating layer in the first sub-pixel, wherein the second insulating layer is disposed between the first electrode and the reflective electrode in the second sub-pixel.

In accordance with some embodiments of the display panel, the individual light-emitting element layer includes a second individual light-emitting element layer disposed in the second sub-pixel, wherein a first insulating layer is disposed between the first electrode in each of the first to third sub-pixels and the substrate, wherein a second insulating layer is disposed between the first electrode and the first insulating layer in the first sub-pixel, wherein the second insulating layer is disposed between the first insulating layer and the reflective electrode in the third sub-pixel.

In accordance with some embodiments of the display panel, the individual light-emitting element layer includes a first individual light-emitting element layer disposed in the first sub-pixel, wherein a first insulating layer is disposed between the substrate and the first electrode in each of the second sub-pixel and the third sub-pixel, wherein a second insulating layer is disposed between the reflective electrode and the first electrode in the second sub-pixel, wherein the second insulating layer is disposed between the first insulating layer and the reflective electrode in the third sub-pixel.

In accordance with some embodiments of the display panel, the individual light-emitting element layer includes a second individual light-emitting element layer and a third individual light-emitting element layer respectively disposed in the second sub-pixel and the third sub-pixel and having different vertical heights, wherein a first insulating layer is disposed between the first electrode in each of the first to third sub-pixels and the substrate, wherein a second insulating layer is disposed between the first electrode and the first insulating layer in the first sub-pixel.

In accordance with some embodiments of the display panel, the individual light-emitting element layer includes a first individual light-emitting element layer and a second individual light-emitting element layer respectively disposed in the first sub-pixel and the second sub-pixel and having different vertical heights, wherein a first insulating layer is disposed between the substrate and the first electrode in each of the second sub-pixel and the third sub-pixel, wherein a second insulating layer is disposed between the reflective electrode and the first insulating layer in the third sub-pixel.

In accordance with some embodiments of the display panel, the individual light-emitting element layer includes a first individual light-emitting element layer and a third individual light-emitting element layer respectively disposed in the first sub-pixel and the third sub-pixel and having different vertical heights, wherein a first insulating layer is disposed between the substrate and the first electrode in each of the second sub-pixel and the third sub-pixel, wherein a second insulating layer is disposed between the first electrode and the reflective electrode in the second sub-pixel.

A display panel comprising: a substrate including a plurality of sub-pixel areas corresponding to a plurality of sub-pixels; a reflective electrode individually disposed in each of the plurality of sub-pixels; a first electrode individually disposed on each of the reflective electrodes and individually disposed in each of the plurality of sub-pixels; an individual light-emitting element layer disposed on each of at least one first electrode; a common light-emitting element layer disposed on the first electrodes and disposed in the plurality of sub-pixels; and a second electrode disposed on the common light-emitting element layer and disposed in the plurality of sub-pixels, wherein respective distances between the reflective electrodes and the first electrodes respectively disposed in the plurality of sub-pixels are different from each other, and/or vertical heights of the individual light-emitting element layers respectively disposed in the plurality of sub-pixels are different from each other.

A display panel comprising: a substrate including a plurality of sub-pixel areas corresponding to a plurality of sub-pixels; a reflective electrode individually disposed in each of the plurality of sub-pixels; a first electrode individually disposed on each of the reflective electrodes and individually disposed in each of the plurality of sub-pixels; a common light-emitting element layer disposed on the first electrodes and disposed in the plurality of sub-pixels; and a second electrode disposed on the common light-emitting element layer and disposed in the plurality of sub-pixels, wherein respective distances between the reflective electrodes and the first electrodes respectively disposed in the plurality of sub-pixels are different from each other.

According to an embodiment of the present disclosure, the individual light-emitting element layer is individually disposed on each of the at least one first electrode, and the common light-emitting element layer is additionally disposed commonly on the individual light-emitting element layers, such that reflection efficiency in a specific sub-pixel may be improved, and luminance in the specific sub-pixel may also be improved. As described above, according to the embodiment of the present disclosure, the luminance of the display panel may be improved, such that power consumption may be reduced by implementing the low power display panel.

In addition, according to an embodiment of the present disclosure, disposing the individual light-emitting element layer in each sub-pixel in addition to adjusting an optical resonance condition via thickness control of the insulating layer disposed on the reflective electrode may allow the light extraction in each sub-pixel to be improved. Accordingly, optimal reflectance and luminous efficiency in each sub-pixel may be secured. As described above, according to the embodiment of the present disclosure, the optimal reflectance and luminous efficiency of the display panel may be secured, such that power consumption may be reduced by implementing a low-power display panel.

In addition, according to an embodiment of the present disclosure, the first individual light-emitting element layer, the second individual light-emitting element layer, and the third individual light-emitting element layer are formed to have different vertical heights, thereby increasing light extraction efficiency and luminance based on the difference between the vertical heights of the individual light-emitting element layers. As described above, according to the embodiment of the present disclosure, the light extraction efficiency of the display panel may be increased and the luminance may be increased, such that power consumption may be reduced by implementing the low power display panel.

In addition, according to an embodiment of the present disclosure, a portion of the insulating layer is patterned to be removed and each of the individual light-emitting element layers is disposed in the patterned area. Thus, a thickness increase may be suppressed by removing a portion of each of the plurality of insulating layers formed for adjusting the optical distance or simplifying the insulating layers into a single layer to efficiently manage the thickness of the display panel. This may minimize the step of the display panel, secure stable thickness uniformity, and improve luminance.

In addition, according to an embodiment of the present disclosure, the individual light-emitting element layer may be additionally disposed selectively in each of the sub-pixels. Thus, the optimized structure suitable for each color is provided in consideration of the light-emitting characteristics of each sub-pixel such as spectrum, light extraction efficiency, and lifespan, thereby achieving balance of the red, green, and blue light emissions and high-quality image implementation.

In addition, according to an embodiment of the present disclosure, via improved light extraction efficiency and thickness management technology, the pixel density may be further increased, and inter-pixel interference may be minimized, thereby implementing an ultra-high resolution panel for a display device such as a virtual reality device or an augmented reality device.

In addition, according to an embodiment of the present disclosure, the efficiency is improved to lower the amount of current required for achieving the same luminance level such that the current density may be reduced, thereby preventing deterioration of the light-emitting material of the light-emitting layer and increasing the lifetime of the light-emitting element. As described above, according to the embodiment of the present disclosure, the lifespan of the light-emitting element of the display panel may be improved, such that the power consumption may be reduced by implementing a low power display panel.

Effects of the present disclosure are not limited to the effects mentioned above, and other effects not mentioned will be clearly understood by those skilled in the art from the description as set forth below. In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a schematic plan view of a display panel.

FIG. 2 is a cross-sectional view of an area I-I′ of FIG. 1 according to a first embodiment.

FIG. 3 is a schematic diagram of a stacked structure of an element of the display panel according to FIG. 2.

FIG. 4 is a cross-sectional view of an area I-I′ of FIG. 1 according to a second embodiment.

FIG. 5 is a schematic diagram illustrating a stacked structure of an element of the display panel according to FIG. 4.

FIGS. 6 to 11 are cross-sectional views of an area I-I′ of FIG. 1 according to third to eighth embodiments, respectively.

FIGS. 12 to 14 are comparisons between electroluminescence spectra in each of sub-pixels of the first embodiment and the second embodiment.

FIG. 15 is a graph showing a comparing result between light efficiencies in each of sub-pixels of the first embodiment and the second embodiment

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements may modify an entirety of the list of elements and may not modify the individual elements of the list. In interpretation of numerical values, an error or tolerance therein may occur even when there is no explicit description thereof. In addition, it will also be understood that when a first element or layer is referred to as being present “on” a second element or layer, the first element may be disposed directly on the second element or may be disposed indirectly on the second element with a third element or layer being disposed between the first and second elements or layers.

It will be understood that when a first element or layer is referred to as being “connected to,” or “coupled to” a second element or layer, the first element may be directly connected to or coupled to the second element or layer, or one or more intervening elements or layers may be present therebetween.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

In addition, it will also be understood that when an element or layer is referred to as being “between” two elements or layers, it may be the only element or layer between the two elements or layers, or one or more intervening elements or layers may also be present therebetween. Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is not indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved. It will be understood that, although the terms “first,” “second,” “third,” and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations. The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, “embodiments,” “examples,” “aspects, etc., should not be construed such that any aspect or design as described is superior to or advantageous over other aspects or designs. Further, the term ‘or’ means ‘inclusive or’ rather than ‘exclusive or.’ That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions. In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified. As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

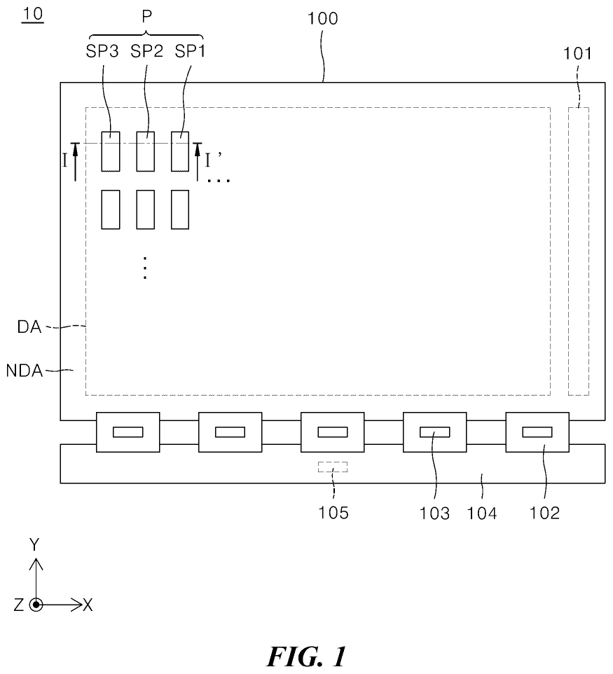

Hereinafter, a display panel and a display device according to an embodiment of the present disclosure will be described in detail with reference to FIG. 1. The display device as described below is embodied as an organic electroluminescence display device (Organic Light-emitting Diodes Display Device) by way of example. However, embodiments of the present disclosure are not limited thereto.

A display panel 10 may include a substrate 100 including a display area DA and a non-display area NDA surrounding a periphery of the display area DA. The display panel 10 may include a substrate 100, a source driving integrated circuit (IC) 103, a flexible film 102, a circuit board 104, and a timing controller 105.

The display area DA on the substrate 100 may include a plurality of sub-pixels SP1, SP2, and SP3 respectively formed in areas in which a plurality of data lines extending in a first direction and a plurality of gate lines extending in a second direction intersecting the first direction intersect each other. The first direction described herein may be an X-axis direction, the second direction may be a Y-axis direction, and the Z-axis direction may be a direction perpendicular to a plane defined by the X-axis and the Y-axis. In addition, in the present disclosure, one pixel P is configured to include the first sub-pixel SP1, the second sub-pixel SP2, and the third sub-pixel SP3. However, embodiments of the present disclosures are not limited thereto, and additional sub-pixels may be further included in one pixel P.

For example, the sub-pixels SP1, SP2, and SP3 may be implemented to emit light of the same color such as the white color or to emit light of different colors, such as red, green, and blue light beams, respectively. Hereinafter, the first sub-pixel SP1 is a red sub-pixel that emits light of red, the second sub-pixel SP2 is a green sub-pixel that emits light of green, and the third sub-pixel SP3 is a blue sub-pixel that emits light of blue. The plurality of sub-pixels SP1, SP2, and SP3 may be arranged in a matrix form arranged in a plurality of rows and columns. In an example, the plurality of sub-pixels may be formed in a stripe structure in which the sub-pixels are linearly arranged in a row direction or a column direction.

A gate driver 101 positioned on one side or each of both opposing sides of the display area DA may be disposed in the non-display area NDA on the substrate 100. The gate driver 101 may be implemented in a Gate-in-panel (GIP) manner. The gate driver 101 may supply gate signals to gate lines according to a gate control signal input from the timing controller 105.

The source driving integrated circuit 103 may receive digital video data and a source control signal from the timing controller 105. The source driving integrated circuit 103 may convert digital video data into analog data voltages according to the source control signal and supply the analog data voltages to the data lines. The source driving integrated circuit 103 may be manufactured as a driving chip of a chip on film (COF) or chip on plastic (COP) type and may be mounted on a plurality of flexible films 102. The circuit board 104 may be attached to the plurality of flexible films 102. A plurality of circuits embodied as driving chips such as the timing controller 105 may be mounted on the circuit board 104.

The timing controller 105 may receive the digital video data and a timing signal from an external system board through a cable of the circuit board 104. The timing controller 105 may supply the gate control signal for controlling an operation timing of the gate driver 101 and the source control signal for controlling the source driving integrated circuits 103 based on the timing signal.

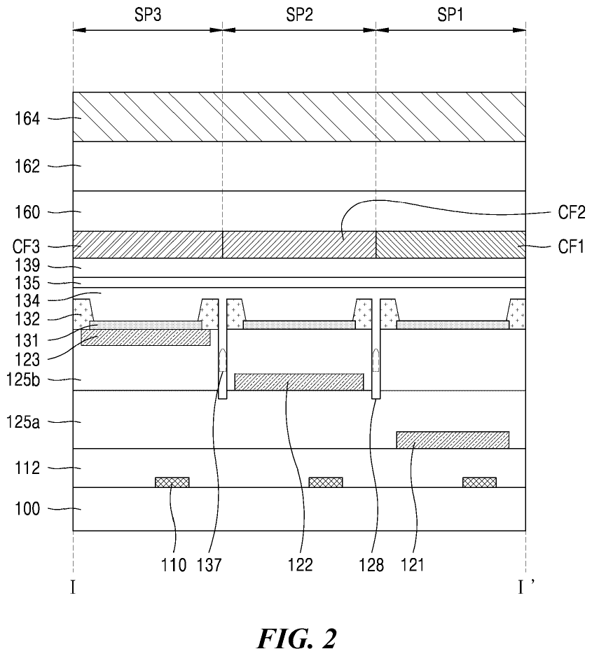

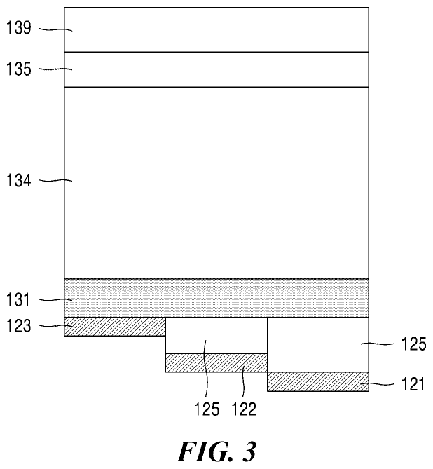

Hereinafter, further with reference to FIGS. 2 and 3, a stacked structure of the display panel 10 according to a first embodiment will be described based on a cross-sectional view. FIG. 2 is a cross-sectional view of an area I-I′ of FIG. 1 according to a first embodiment. FIG. 3 is a schematic diagram of a stacked structure of an element of the display panel according to FIG. 2.

The substrate 100 may be made of glass or plastic such as polyimide. However, embodiments of the present disclosure are not limited thereto, and the substrate 100 may be made of a semiconductor material such as a silicon wafer. For example, the substrate 100 may embodied as be a single crystal silicon wafer formed by growing single crystal silicon (Si), or may be embodied as a wafer made of various semiconductor materials. Hereinafter, an embodiment for an OLEDoS (OLED on Si wafer) structure in which a common light-emitting element layer 134 including an organic light-emitting element is disposed on the substrate 100 embodied as the silicon wafer will be described. However, embodiments of the present disclosure are not limited thereto.

A circuit area 110 may be disposed on the substrate 100. The circuit area 110 may be disposed in each of the sub-pixels SP1, SP2, and SP3 included in the display panel 10. The circuit area 110 may be electrically connected to the light-emitting element layer disposed on the circuit area 110. For example, the circuit area 110 may include various signal lines such as a gate line, a data line, various circuit-related elements including a thin-film transistor, a storage capacitor, and the like. The thin-film transistor TFT may include a switching thin-film transistor, a driving thin-film transistor, a sensing thin-film transistor, etc. However, embodiments of the present disclosure are not limited thereto, and the circuit area may include a Complementary Metal Oxide Semiconductor (CMOS) transistor.

The display panel 10 may further include a circuit area insulating layer 112, a first reflective electrode 121, a first insulating layer 125a, a second reflective electrode 122, a second insulating layer 125b, and a third reflective electrode 123, which are disposed on the circuit area 110.

Each of the circuit area insulating layer 112, the first insulating layer 125a, and the second insulating layer 125b may be formed as a single layer or a stack of multiple layers made of an inorganic material such as silicon nitride, aluminum nitride, zirconium nitride, titanium nitride, hafnium nitride, tantalum nitride, silicon oxide, aluminum oxide, or titanium oxide. However, embodiments of the present disclosure are not limited thereto, and each of the circuit area insulating layer 112, the first insulating layer 125a, and the second insulating layer 125b may may be formed as a single layer or a stack of multiple layers made of an organic material such as acrylic resin, epoxy resin, phenolic resin, polyamide resin, polyimide resin, or the like.

Each of the first reflective electrode 121, the second reflective electrode 122, and the third reflective electrode 123 may include a metal material having high reflection efficiency, and may be made of, for example, silver (Ag) or a metal material including silver (Ag). However, embodiments of the present disclosure are not limited thereto.

The circuit area insulating layer 112 may be disposed on the circuit area 110 so as to cover an entire surface of the substrate 100. The first reflective electrode 121 may be disposed in the first sub-pixel SP1 and on the circuit area insulating layer 112. That is, each of the first reflective electrodes 121 may be disposed in each of a plurality of first sub-pixels SP1.

The first insulating layer 125a may be disposed on the first reflective electrode 121 so as to cover the entire surface of the substrate 100. The second reflective electrode 122 may be disposed in the second sub-pixel SP2 and on the first insulating layer 125a. That is, each of the second reflective electrodes 122 may be disposed in each of a plurality of second sub-pixels SP2.

The second insulating layer 125b may be disposed on the second reflective electrode 122 so as to cover the entire surface of the substrate 100. The third reflective electrode 123 may be disposed in the third sub-pixel SP3 and on the second insulating layer 125b. That is, each of the third reflective electrodes 123 may be disposed in each of a plurality of third sub-pixels SP3.

A first electrode 131 may be disposed on each of the first reflective electrode 121, the second reflective electrode 122, and the third reflective electrode 123. That is, each of the first electrodes 131 may be disposed in each of the plurality of sub-pixels SP. The first electrodes 131 may be electrically connected to the common light-emitting element layer 134 to be described later, and may function as an anode electrode. For example, the first electrode 131 may include a transparent conductive material or a transflective metal material. However, embodiments of the present disclosure are not limited thereto.

The first electrode 131 disposed on the third reflective electrode 123 may directly contact the third reflective electrode 123. However, embodiments of the present disclosure are not limited thereto. For example, a third insulating layer formed on the third reflective electrode 123 so as to cover the entire surface of the substrate 100 may be additionally disposed between the third reflective electrode 123 and the first electrode 131, so that the third reflective electrode 123 and the first electrode 131 may not be in contact with each other but may be disposed to be spaced apart from each other by a predetermined distance.

Each of the first electrodes 131 may be disposed between adjacent sub-pixels SP. The first electrodes 131 may be disposed to be spaced apart from each other. A bank layer 132 may be disposed on the first electrode 131. The bank layer 132 may be formed to cover each of both opposing side ends of the first electrode 131, thereby preventing current from being concentrated on the end of the first electrode 131. The bank layer 132 may be formed as a single layer made of an insulating material made of an inorganic material such as silicon nitride (SiNx) or silicon oxide (SiOx), or be formed as a stack of a plurality of layers made of an inorganic material such as silicon nitride (SiNx) or silicon oxide (SiOx). However, embodiments of the present disclosure are not limited thereto. In addition, the bank layer 132 may be made of an organic material, and may include, for example, a material made of polyimide, acryl, or benzocyclobutene-based resin. In addition, the bank layer 132 may be embodied as a black bank including a black material. The bank layer 132 may be referred to as a fence.

A trench 128 may be formed between portions of the bank layer 132 at a boundary between adjacent sub-pixels. The trench 128 may be formed by removing a partial area of the insulating layer. For example, the trench 128 may extend through the second insulating layer 125b and be formed in a form of a concave groove that is recessed downwardly in the first insulating layer 125a so as to have a predetermined left and right width and a predetermined vertical height. The trench 128 may be formed at the boundary between adjacent ones of a plurality of sub-pixels SP.

The common light-emitting element layer 134 may be disposed on the first electrode 131. The common light-emitting element layer 134 may be formed as a single stack. However, embodiments of the present disclosures are not limited thereto, and the common light-emitting element layer 134 may have a tandem structure of two stacks in which a first stack, a charge generation layer (CGL), and a second stack are stacked, or a tandem structure of three stacks in which a first stack, a first charge generation layer (CGL), a second stack, a second charge generation layer (CGL), and a third stack are stacked. The number of the stacks in the tandem structure is not limited thereto.

When the common light-emitting element layer 134 is formed as a single stack, the common light-emitting element layer 134 may include a hole injection layer (HIL), a hole transport layer (HTL), a light-emitting material layer (EML), an electron transport layer (ETL), and an electron injection layer (EIL).

When the common light-emitting element layer 134 includes the first stack, the charge generation layer, and the second stack, the first stack may include the hole injection layer (HIL), the hole transport layer (HTL), the light-emitting material layer (EML), and the electron transport layer (ETL). The light-emitting material layer (EML) of the first stack may emit one of red light, green light, blue light, and yellow light. The charge generation layer may include a negative type (N-type) charge generation layer for supplying electrons to the first stack, and a positive type (P-type) charge generation layer for supplying holes to the second stack. The second stack may include the hole transport layer (HTL), the light-emitting material layer (EML), the electron transport layer (ETL), and the electron injection layer (EIL). The light-emitting material layer (EML) of the second stack may emit one of red light, green light, blue light, and yellow light. The light-emitting material layer (EML) of the first stack and the light-emitting material layer (EML) of the second stack emit light of different colors, so that the common light-emitting element layer 134 including the first stack and the second stack may emit white light.

The common light-emitting element layer 134 disposed on the first electrode 131 may be formed over the entire surface of the substrate 100 so as to cover the sub-pixels SP adjacent to each other and the bank layer 132 disposed therebetween. In this case, the common light-emitting element layer 134 may be disposed to fill the trench 128. A void 137 having a hollow may be formed inside a portion of the common light-emitting element layer 134 in the trench 128. The void 137 may serve to disconnect the charge generation layers CGL respectively disposed in adjacent ones of the plurality of sub-pixels from each other in the horizontal direction. As the void 137 is formed in the trench 128 as described above, the generation of a lateral leakage current that may occur due to a short-circuit between the respective charge generation layers CGL of the sub-pixels adjacent to each other may be reduced

A second electrode 135 may be disposed on the common light-emitting element layer 134. The second electrode 135 may be formed over the entire surface of the substrate 100 so as to be commonly connected to the common light-emitting element layer 134 commonly disposed in all sub-pixels. Accordingly, the second electrode 135 may be referred to as a common electrode. The second electrode 135 may be electrically connected to the common light-emitting element layer 134 and may function as a cathode electrode. For example, the second electrode 135 may include a transparent conductive material such as indium tin oxide (ITO) or indium zinc oxide (IZO) or a transflective conductive material. However, embodiments of the present disclosure are not limited thereto.

An encapsulation layer 139 that blocks external moisture and oxygen may be formed on the second electrode 135. The encapsulation layer 139 may include an inorganic insulating material such as silicon oxide (SiOx) and silicon nitride (SiNx) or an organic insulating material such as acrylic resin and epoxy resin, and may be formed as a single layer or a stack of multiple layers.

A color filter layer CF1, CF2, and CF3 may be disposed on the encapsulation layer 139. For example, the color filter layer may include a red first color filter layer CF1 provided in the first sub-pixel SP1, a green second color filter layer CF2 provided in the second sub-pixel SP2, and a blue third color filter layer CF3 provided in the third sub-pixel SP3. For example, the first color filter layer CF1 may include a red pigment or a red dye, the second color filter layer CF2 may include a green pigment or a green dye, and the third color filter layer CF3 may include a blue pigment or a blue dye. The color filter layer may be made of an organic material having a relatively high transmittance.

The common light-emitting element layer 134 according to an embodiment of the present disclosure may be implemented to emit white light. Accordingly, in the first sub-pixel SP1, after white light emitted from the common light-emitting element layer 134 transmits through the first color filter CF1, only red light may be emitted therefrom. In the second sub-pixel SP2, after white light emitted from the common light-emitting element layer 134 transmits through the second color filter CF2, only green light may be emitted therefrom. In the third sub-pixel SP3, after white light emitted from the common light-emitting element layer 134 transmits through the third color filter CF3, only blue light may be emitted therefrom.

A planarization layer 160 may be disposed on the color filter layers CF1, CF2, and CF3. The planarization layer 160 may be made of an organic material. A cover layer 164 may be disposed on the planarization layer 160. For example, the cover layer 164 may be a cover glass made of a glass material. The cover layer 164 may be disposed on the planarization layer 160 via an adhesive layer 162.

Each of the first reflective electrode 121, the second reflective electrode 122, and the third reflective electrode 123 may reflect light emitted from the common light-emitting element layer 134 in an upward direction toward the second electrode 135. That is, the light beams respectively emitted from the common light-emitting element layer 134 may be reflected between the second electrode 135 and the first reflective electrode 121, the second reflective electrode 122, and the third reflective electrode 123 to constructively interfere with each other, and then may travel through the second electrode 135 and be emitted to the outside.

Since the first reflective electrode 121, the second reflective electrode 122, and the third reflective electrode 123 are disposed in different layers, respective spacings from the first reflective electrode 121, the second reflective electrode 122, and the third reflective electrode 123 respectively disposed in the sub-pixels emitting light of different colors to the second electrode 135 may be set to different from each other.

For example, a first distance which is a distance between the first reflective electrode 121 and the second electrode 135 may be greater than a second distance which is a distance between the second reflective electrode 122 and the second electrode 135. The second distance which is a distance between the second reflective electrode 122 and the second electrode 135 may be greater than a third distance which is a distance between the third reflective electrode 123 and the second electrode 135. As described above, the first distance, the second distance, and the third distance are different from each other, such that the light of different colors may be extracted using microcavity characteristics.

Specifically, as a distance between the reflective electrode and the second electrode 135 increases, the light extraction efficiency of the long wavelength may be improved, and thus the light extraction efficiency of the red light between the first reflective electrode 121 and the second electrode 135 may be improved. As the distance between the reflective electrode and the second electrode 135 decreases, the light extraction efficiency of the short wavelength may be improved, and thus the light extraction efficiency of the blue light between the third reflective electrode 123 and the second electrode 135 may be improved. In addition, since the distance between the second reflective electrode 122 and the second electrode 135 is smaller than the distance between the first reflective electrode 121 and the second electrode 135 and is larger than the distance between the third reflective electrode 123 and the second electrode 135, light extraction efficiency of green light may be improved.

Referring to FIG. 3, an insulating layer 125 including a first insulating layer 125a and a second insulating layer 125b may be formed between the first reflective electrode 121 and the first electrode 131. The insulating layer 125 including the second insulating layer 125b may be formed between the second reflective electrode 122 and the first electrode 131. Accordingly, a vertical height of a portion of the insulating layer 125 formed between the second reflective electrode 122 and the first electrode 131 may be smaller than a vertical height of a portion of the insulating layer 125 formed between the first reflective electrode 121 and the first electrode 131. The first insulating layer 125a and the second insulating layer 125b are not formed between the third reflective electrode 123 and the first electrode 131, and the third reflective electrode 123 and the first electrode 131 may be in contact with each other.

Accordingly, according to the present disclosure, the microcavity structure is applied to the display panel 10 to emit light, such that the light extraction efficiency of red light is improved in the first sub-pixel SP1 to emit red light, the light extraction efficiency of green light is improved in the second sub-pixel SP2 to emit green light, and the light extraction efficiency of blue light is improved in the third sub-pixel SP3 to emit blue light.

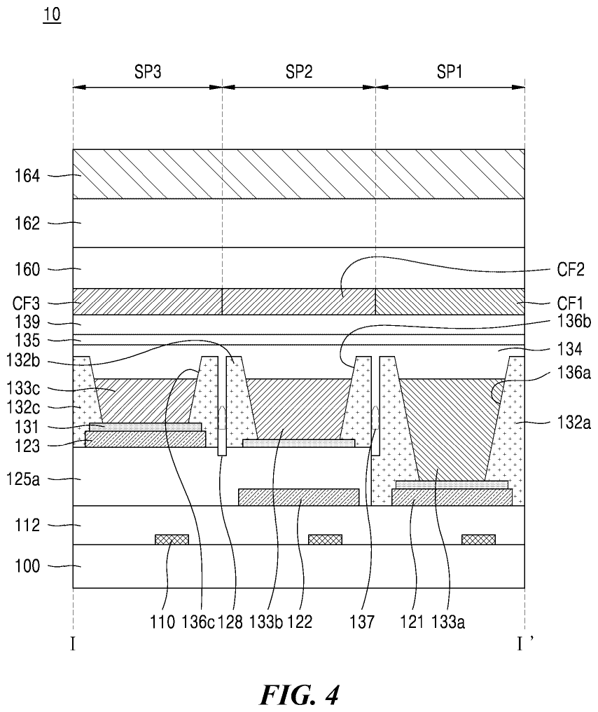

Hereinafter, a stacked structure of the display panel 10 according to various embodiments will be described with reference to FIGS. 4 to 11. The stacked structure of the display panel 10 according to various embodiments as described below will be mainly described based on difference thereof from the stacked structure of the display panel 10 according to the first embodiment as described above. Therefore, those duplicate with the descriptions of the display panel 10 according to the first embodiment are omitted below.

The display panel 10 may further include an individual light-emitting element layer disposed on at least one first electrode 131. The common light-emitting element layer 134 may be disposed on the individual light-emitting element layer, and the second electrode 135 may be disposed on the common light-emitting element layer 134.

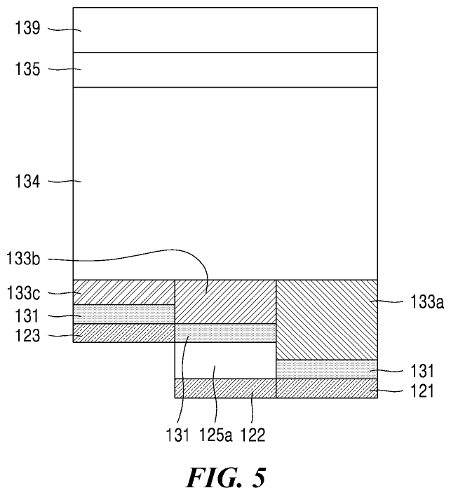

Referring to FIGS. 4 and 5, the display panel 10 according to a second embodiment may include a first individual light-emitting element layer 133a, a second individual light-emitting element layer 133b, and a third individual light-emitting element layer 133c, which are respectively disposed in the first sub-pixel SP1, the second sub-pixel SP2, and the third sub-pixel SP3 and have different vertical heights. In this case, vertical heights of the first individual light-emitting element layer 133a, the second individual light-emitting element layer 133b, and the third individual light-emitting element layer 133c may decrease in this order. That is, the vertical height of the first individual light-emitting element layer 133a may be set to be the greatest, and the vertical height of the third individual light-emitting element layer 133c may be set to be the smallest.

For example, the first individual light-emitting element layer 133a may include a hole injecting layer (HIL), a hole transporting layer (HTL), a red light-emitting material layer (R-EML), and an electron transporting layer (ETL), and may be an element emitting red light. The second individual light-emitting element layer 133b may include a hole injecting layer (HIL), a hole transporting layer (HTL), a green light-emitting material layer (G-EML), and an electron transporting layer (ETL), and may be an element emitting green light. The third individual light-emitting element layer 133c may include a hole injecting layer (HIL), a hole transporting layer (HTL), a blue light-emitting material layer (B-EML), and an electron transporting layer (ETL), and may be an element emitting blue light.

The first reflective electrode 121 may be disposed on a portion of the circuit area insulating layer 112 corresponding to the first sub-pixel SP1. The first electrode 131 may be disposed on the first reflective electrode 121, and the first electrode 131 may be disposed to be in contact with the first reflective electrode 121. Accordingly, a separate insulating layer may not exist between the first reflective electrode 121 and the first electrode 131. A first bank layer 132a may be disposed on the first electrode 131. The first bank layer 132a may be formed to cover each of both opposing side ends of the first electrode 131 and may define a boundary between a corresponding sub-pixel and each of both opposing sub-pixels therearound. The first bank layer 132a may be formed to cover each of both opposing side ends of the first reflective electrode 121 disposed under the first electrode 131. In addition, the first bank layer 132a covering each of both opposing side ends of the first reflective electrode 121 and extending out of the first reflective electrode 121 may be disposed on the circuit area insulating layer 112. Accordingly, the first bank layer 132a and the first reflective electrode 121 may be disposed in the same layer on the circuit area insulating layer 112. In addition, the first bank layer 132a and the first reflective electrode 121 may be in contact with the circuit area insulating layer 112.

The second reflective electrode 122 may be disposed on a portion of the circuit area insulating layer 112 corresponding to the second sub-pixel SP2. The first insulating layer 125a may be disposed on the second reflective electrode 122. The first insulating layer 125a may be formed to extend into the third sub-pixel SP3. That is, the first insulating layer 125a may be disposed in an area corresponding to the second sub-pixel SP2 and the third sub-pixel SP3, but may not be disposed in an area corresponding to the first sub-pixel SP1. Accordingly, the first insulating layer 125a and the first bank layer 132a disposed on the circuit area insulating layer 112 may be disposed in the same layer. The first electrode 131 may be disposed on a portion of the first insulating layer 125a corresponding to the second sub-pixel SP2, and a second bank layer 132b may be disposed on the first electrode 131. The second bank layer 132b may be formed to cover each of both opposing side ends of the first electrode 131 and may define a boundary between a corresponding sub-pixel and each of both opposing sub-pixels therearound. In addition, the second bank layer 132b and the first electrode 131 corresponding to the second sub-pixel SP2 may be in contact with the first insulating layer 125a. As described above, the first insulating layer 125a may be disposed between the second reflective electrode 122 and the first electrode 131 in the second sub-pixel SP2.

The first insulating layer 125a may be disposed on a portion of the circuit area insulating layer 112 corresponding to the third sub-pixel SP3. The third reflective electrode 123 may be disposed on the first insulating layer 125a corresponding to the third sub-pixel SP3. The first electrode 131 may be disposed on the third reflective electrode 123, and the first electrode 131 may be disposed in contact with the third reflective electrode 123. Accordingly, a separate insulating layer may not exist between the third reflective electrode 123 and the first electrode 131. A third bank layer 132c may be disposed on the first electrode 131 corresponding to the third sub-pixel SP3. The third bank layer 132c may be formed to cover each of both opposing side ends of the first electrode 131 and may define a boundary between a corresponding sub-pixel and each of both opposing sub-pixels therearound. The third bank layer 132c may be formed to cover each of both opposing side ends of the third reflective electrode 123 disposed under the first electrode 131. In addition, the third bank layer 132c covering each of both opposing side ends of the third reflective electrode 123 and extending out of the third reflective electrode 123 may be disposed on the first insulating layer 125a.

The third bank layer 132c and the second bank layer 132b may be disposed in the same layer on the first insulating layer 125a. In addition, the third reflective electrode 123 and the first electrode 131 corresponding to the second sub-pixel SP2 may be disposed in the same layer on the first insulating layer 125a. Accordingly, all of the third bank layer 132c, the second bank layer 132b, the third reflective electrode 123, and the first electrode 131 corresponding to the second sub-pixel SP2 may be disposed in the same layer on the first insulating layer 125a. In addition, the third bank layer 132c and the third reflective electrode 123 may contact the first insulating layer 125a.

The distance between the third reflective electrode 123 and the second electrode 135 of the third sub-pixel SP3 may be smaller than each of the distance between the first reflective electrode 121 and the second electrode 135 of the first sub-pixel SP1 and the distance between the second reflective electrode 122 and the second electrode 135 of the second sub-pixel SP2.

A first patterned area 136a, a second patterned area 136b, and a third patterned area 136c may be formed inside the first bank layer 132a, the second bank layer 132b, and the third bank layer 132c, respectively. A vertical height of the first bank layer 132a may be greater than each of a vertical height of the second bank layer 132b and a vertical height of the third bank layer 132c. For example, each of a sum of the vertical height of the first insulating layer 125a and the vertical height of the second bank layer 132b and a sum of the vertical height of the first insulating layer 125a and the vertical height of the third bank layer 132c may be substantially equal to the vertical height of the first bank layer 132a.

In addition, a depth of the first patterned area 136a may be greater than each of a depth of the second patterned area 136b and a depth of the third patterned area 136c. The first individual light-emitting element layer 133a, the second individual light-emitting element layer 133b, and the third individual light-emitting element layer 133c may be disposed in the first patterned area 136a, the second patterned area 136b, and the third patterned area 136c, respectively. The first individual light-emitting element layer 133a, the second individual light-emitting element layer 133b, and the third individual light-emitting element layer 133c may be formed in various types of patterning processes such as a fine metal mask (FMM) scheme, an inkjet printing scheme, and a photo process.

Since the depths of the first patterned area 136a, the second patterned area 136b, and the third patterned area 136c are different from each other, the vertical heights of the first individual light-emitting element layer 133a, the second individual light-emitting element layer 133b, and the third individual light-emitting element layer 133c may also be different from each other. In this case, vertical levels of upper ends of the first individual light-emitting element layer 133a, the second individual light-emitting element layer 133b, and the third individual light-emitting element layer 133c may be equal to each other. In one example, the depths of the second patterned area 136b and the third patterned area 136c may be substantially equal to each other. However, in the second sub-pixel SP2, only the first electrode 131 is positioned on the first insulating layer 125a, while in the third sub-pixel SP3, not only the first electrode 131 but also the third reflective electrode 123 are positioned on the first insulating layer 125a. Thus, the vertical height of the third individual light-emitting element layer 133c may be substantially smaller than the vertical height of the second individual light-emitting element layer 133b.

Referring to FIG. 5, an insulating layer is not formed between the first reflective electrode 121 and the first electrode 131, and the first reflective electrode 121 and the first electrode 131 may be in contact with each other. The first individual light-emitting element layer 133a may be disposed on the first electrode 131 on the first reflective electrode 121. The first insulating layer 125a may be disposed between the second reflective electrode 122 and the first electrode 131. The first electrode 131 may be disposed on the first insulating layer 125a on the second reflective electrode 122, and the second individual light-emitting element layer 133b may be disposed on the first electrode 131. An insulating layer is not formed between the third reflective electrode 123 and the first electrode 131, and the third reflective electrode 123 and the first electrode 131 may contact each other. The third individual light-emitting element layer 133c may be disposed on the first electrode 131 on the third reflective electrode 123.

According to the embodiment of the present disclosure as described above, disposing the individual light-emitting element layers on at least the first electrode, respectively, and additionally disposing the common light-emitting element layer on the individual light-emitting element layers may result in improvement of both reflection efficiency and luminance in a specific sub-pixel.

In addition, according to an embodiment of the present disclosure, disposing the individual light-emitting element layer in each sub-pixel in addition to adjusting an optical resonance condition via thickness control of the insulating layer disposed on the reflective electrode may allow the light extraction in each sub-pixel to be improved. Accordingly, optimal reflectance and luminous efficiency in each sub-pixel may be secured.

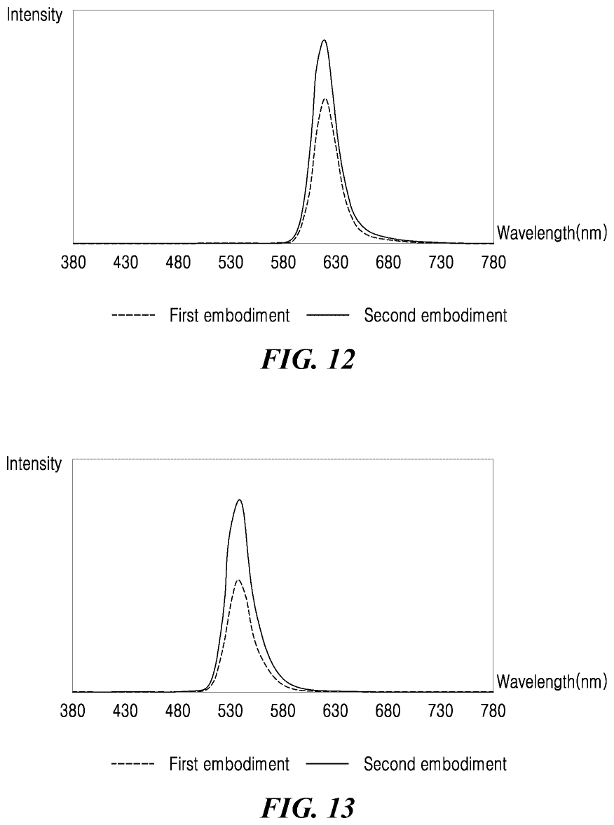

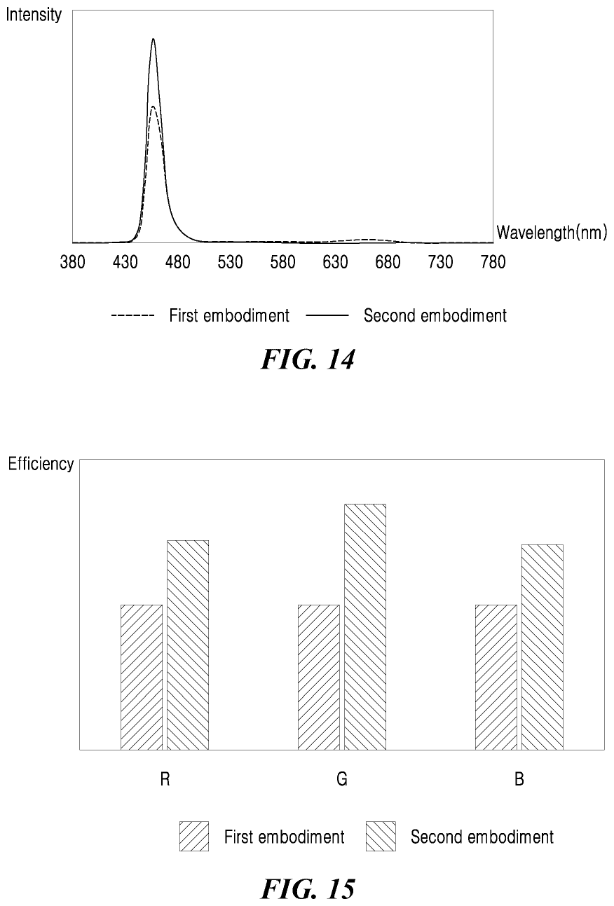

Referring to FIGS. 12 to 14, the electroluminescence (EL) spectra in each of the sub-pixels of the first embodiment and the second embodiment are compared with each other based on a relative value. FIG. 12 is a graph of a comparison between the electroluminescence spectra in the first sub-pixel, and it may be identified that the luminance in the second embodiment is improved compared to the first embodiment. In addition, FIG. 13 is a graph of a comparison of the electroluminescence spectra in the second sub-pixel, and it may be identified that the luminance in the second embodiment is significantly improved compared to the first embodiment. In addition, FIG. 14 is a graph of a comparison of the electroluminescence spectra of the third sub-pixel, and it may be identified that the luminance in the second embodiment is improved compared to the first embodiment.

The light efficiency in each sub-pixel may vary depending on the optical distance controlled based on the position of the light-emitting layer between the reflective electrode and the second electrode as the cathode electrode. In the second embodiment, it may be identified that in the second sub-pixel, the luminance improvement effect is greater by adjusting the optical distance so that the light efficiency is relatively higher than that in each of the first sub-pixel and the third sub-pixel.

Thus, in the embodiment of the present disclosure, it may be identified that a portion of the insulating layer is patterned to be removed in each sub-pixel and the individual light-emitting element layer is additionally disposed in the patterned area in each sub-pixel in addition to the common light-emitting element layer, such that luminance is improved in each of all of the sub-pixels emitting light of different colors.

FIG. 15 is a graph showing a comparing result between light efficiencies in each of sub-pixels of the first embodiment and the second embodiment based on a relative value. As may be identified in FIG. 15, it may be identified that in each of all of the first sub-pixel SP1, the second sub-pixel SP2, and the third sub-pixel SP3, the light emission efficiency of the second embodiment is increased compared to that of the first embodiment. In particular, it may be identified that in the second sub-pixel SP2 emitting light of the green color among the first sub-pixel SP1, the second sub-pixel SP2, and the third sub-pixel SP3, the light efficiency is significantly improved compared to the first sub-pixel SP1 and the third sub-pixel SP3 respectively emitting light beams of the red and blue colors.

Thus, it may be clearly identified that not only luminance but also light efficiency is improved in all of the sub-pixels in the second embodiment compared to the first embodiment. In particular, it may be identified that the improvement effect is more prominent in the second sub-pixel emitting light of the green color. Therefore, according to the second embodiment, not only the luminance but also the light efficiency of each of the sub-pixels may be maximized due to the additional arrangement of the individual light-emitting element layer.

In addition, according to an embodiment of the present disclosure, the first individual light-emitting element layer, the second individual light-emitting element layer, and the third individual light-emitting element layer are formed to have different vertical heights, thereby increasing light extraction efficiency and increasing luminance based on the difference between the vertical heights of the individual light-emitting element layers.

In addition, according to an embodiment of the present disclosure, a portion of the insulating layer is patterned to be removed and each of the individual light-emitting element layers is disposed in the patterned area. Thus, a thickness increase may be suppressed by removing a portion of each of the plurality of insulating layers formed for adjusting the optical distance or simplifying the insulating layers into a single layer to efficiently manage the thickness of the display panel. This may minimize the step of the display panel, secure stable thickness uniformity, and improve luminance.

For example, a stacked structure of an element of a display panel according to the first embodiment may be compared with a stacked structure of an element of a display panel according to the second embodiment with reference to FIG. 5. Referring to FIG. 3, in the first embodiment, depending on each sub-pixel, the insulating layer 125 including the first insulating layer 125a and the second insulating layer 125b or the insulating layer 125 including only the second insulating layer 125b or no insulating layer 125 is disposed between the reflective electrode and the first electrode 131. On the other hand, referring to FIG. 5, in the second embodiment, when the individual light-emitting element layer is formed in each sub-pixel, the insulating layer is entirely removed or a portion of the insulating layer 125 such as the first insulating layer 125a is present, such that the individual light-emitting element layer may be added in a state in which the thickness of the display panel is not increased.

That is, in the first embodiment, the insulating layer of the double insulating layer structure is formed to adjust the optical distance for obtaining the microcavity effect in the OLEDoS structure. However, in the second embodiment, the optical distance may be adjusted only by removing one of the double insulating layers and leaving the other thereof only in each of some sub-pixels. In this case, the optical distance may be adjusted by adjusting the thickness of the individual light-emitting element layer added instead of the insulating layer in each sub-pixel.

In addition, according to an embodiment of the present disclosure, as the insulating layer disposed between the reflective electrode and the first electrode 131 is simplified from the double layer structure to a single layer structure, the number of insulating layers disposed between the circuit area 110 and the first electrode 131 is also reduced. Accordingly, the number of contact holes required to electrically connect the circuit area 110 and the first electrode 131 may be further reduced by at least one. As the number of contact holes formed in the insulating layer is reduced, an advantageous effect of increasing the aperture ratio of the display panel 10 may be obtained.

The display panel as described above may be applied to various types of display devices. In an example, the display panel 10 according to an embodiment of the present disclosure may be included in a head-mounted display device. The head-mounted display device may provide a user with an image implementing a Virtual Reality (VR) or an image implementing an Augmented Reality (AR). Therefore, according to an embodiment of the present disclosure, via improved light extraction efficiency and thickness management technology, the pixel density may be further increased, and inter-pixel interference may be minimized, thereby implementing an ultra-high resolution panel for a display device such as a virtual reality device or an augmented reality device.

In one example, the display panel 10 according to an embodiment of the present disclosure may be implemented in various embodiments as follows. For example, in third to eighth embodiments as described below, an individual light-emitting element layer may be selectively additionally disposed in each sub-pixel.

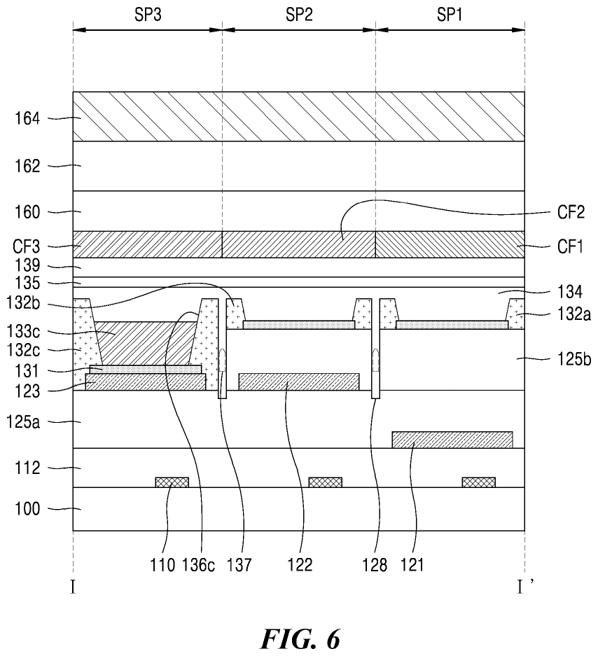

Referring to FIG. 6, in the display panel 10 according to the third embodiment, a third individual light-emitting element layer 133c may be disposed in the third sub-pixel SP3. In this case, a separate light-emitting element layer may not be disposed in each of the first sub-pixel SP1 and the second sub-pixel SP2. In addition, the first insulating layer 125a may be disposed on the substrate 100 corresponding to the first sub-pixel SP1, the second sub-pixel SP2, and the third sub-pixel SP3. In this case, the first reflective electrode 121 may be disposed between the circuit area insulating layer 112 and the first insulating layer 125a in the first sub-pixel SP1. In addition, the second reflective electrode 122 and the third reflective electrode 123 may be disposed on the first insulating layer 125a in the second sub-pixel SP2 and the third sub-pixel SP3, respectively. The second insulating layer 125b may be disposed in the first sub-pixel SP1 and the second sub-pixel SP2.

The first electrode 131 may be disposed on the second insulating layer 125b of the first sub-pixel SP1, and the first bank layer 132a may be disposed on the second insulating layer 125b of the first sub-pixel SP1 so as to cover each of both opposing side ends of the first electrode 131. Therefore, in the first sub-pixel SP1, the first insulating layer 125a and the second insulating layer 125b may be disposed between the first reflective electrode 121 and the first electrode 131. The first electrode 131 may be disposed on the second insulating layer 125b of the second sub-pixel SP2, and the second bank layer 132b may be disposed on the second insulating layer 125b of the second sub-pixel SP2 so as to cover each of both opposing side ends of the first electrode 131. Therefore, in the second sub-pixel SP2, the second insulating layer 125b may be disposed between the second reflective electrode 122 and the first electrode 131. The first electrode 131 may be disposed on the third reflective electrode 123 of the third sub-pixel SP3 to be in contact with the third reflective electrode 123. The third bank layer 132c having the third patterned area 136c defined therein may be disposed on the first insulating layer 125a so as to cover each of both opposing side ends of the first electrode 131. Accordingly, the third bank layer 132c and the second insulating layer 125b on the first insulating layer 125a may be formed in the same layer. The third individual light-emitting element layer 133c may be disposed in the third patterned area 136c.

According to the third embodiment, when the display panel 10 lacks a blue color light emission ability, the third individual light-emitting element layer 133c may be additionally disposed in the third sub-pixel SP3 that emits blue color, thereby improving the luminance of blue light to balance luminance of the red, green, and blue light of the display panel 10.

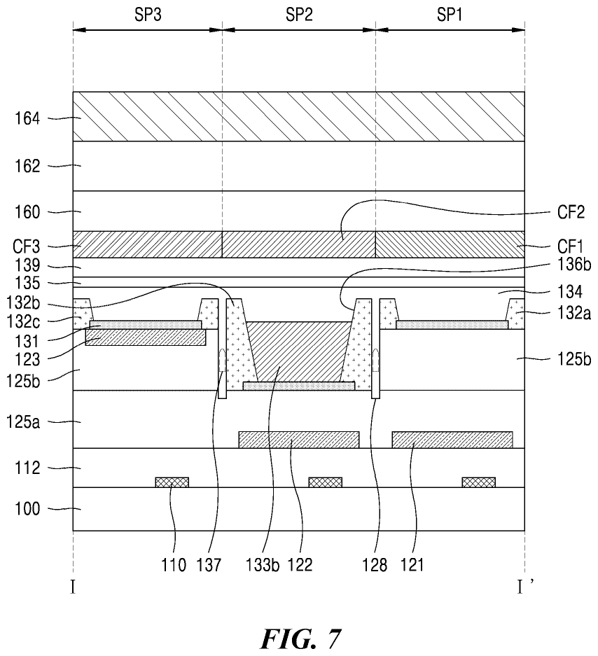

Referring to FIG. 7, in the display panel 10 according to the fourth embodiment, the second individual light-emitting element layer 133b may be disposed in the second sub-pixel SP2. In this case, a separate light-emitting element layer may not be disposed in each of the first sub-pixel SP1 and the third sub-pixel SP3. In addition, the first insulating layer 125a may be disposed on the substrate 100 corresponding to the first sub-pixel SP1, the second sub-pixel SP2, and the third sub-pixel SP3. In this case, the first reflective electrode 121 and the second reflective electrode 122 may be disposed between the circuit area insulating layer 112 and the first insulating layer 125a in the first sub-pixel SP1 and the second sub-pixel SP2, respectively. The second insulating layer 125b may be disposed on the first insulating layer 125a of each of the first sub-pixel SP1 and the third sub-pixel SP3.

The first electrode 131 may be disposed on the second insulating layer 125b of the first sub-pixel SP1, and the first bank layer 132a may be disposed on the second insulating layer 125b of the first sub-pixel SP1 so as to cover each of both opposing side ends of the first electrode 131. Therefore, in the first sub-pixel SP1, the first insulating layer 125a and the second insulating layer 125b may be disposed between the first reflective electrode 121 and the first electrode 131. The third reflective electrode 123 may be disposed on the second insulating layer 125b of the third sub-pixel SP3. The first electrode 131 may be disposed on the third reflective electrode 123 to be in contact therewith, and the third bank layer 132c may be disposed on the second insulating layer 125b of the third sub-pixel SP3 so as to cover each of both opposing side ends of the first electrode 131. The first electrode 131 may be disposed on the first insulating layer 125a of the second sub-pixel SP2. Therefore, in the second sub-pixel SP2, the first insulating layer 125a may be disposed between the second reflective electrode 122 and the first electrode 131. The second bank layer 132b having the second patterned area 136b defined therein may be disposed on the first insulating layer 125a of the second sub-pixel SP2 so as to cover each of both opposing side ends of the first electrode 131. Accordingly, the second bank layer 132b and the second insulating layer 125b on the first insulating layer 125a may be positioned in the same layer. The second individual light-emitting element layer 133b may be disposed in the second patterned area 136b.

According to the fourth embodiment, when the display panel 10 lacks a green light emission ability, the second individual light-emitting element layer 133b is additionally disposed in the second sub-pixel SP2 to emit green light, thereby improving the luminance of green light to balance luminance of the red, green, and blue light of the display panel 10.

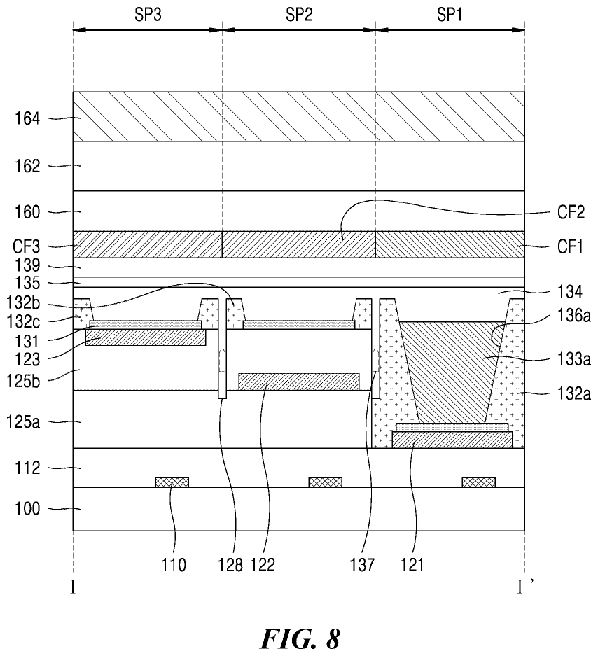

Referring to FIG. 8, in the display panel 10 according to the fifth embodiment, the first individual light-emitting element layer 133a may be disposed in the first sub-pixel SP1. In this case, a separate light-emitting element layer may not be disposed in each of the second sub-pixel SP2 and the third sub-pixel SP3. In addition, the first insulating layer 125a may be disposed on the substrate 100 corresponding to the second sub-pixel SP2 and the third sub-pixel SP3. The second insulating layer 125b may be disposed on the first insulating layer 125a of the second sub-pixel SP2 and the third sub-pixel SP3. In this case, the second reflective electrode 122 may be disposed between the first insulating layer 125a and the second insulating layer 125b of the second sub-pixel SP2. The first electrode 131 and the second bank layer 132b may be disposed on the second insulating layer 125b of the second sub-pixel SP2. The third reflective electrode 123 may be disposed on the second insulating layer 125b of the third sub-pixel SP3. The first electrode 131 may be disposed on the third reflective electrode 123 to be in contact therewith, and the third bank layer 132c may be disposed on the second insulating layer 125b of the third sub-pixel SP3 so as to cover each of both opposing side ends of the first electrode 131.

The first reflective electrode 121 may be disposed on the circuit area insulating layer 112 on the substrate 100 of the first sub-pixel SP1. The first electrode 131 may be disposed on the first reflective electrode 121 to be in contact therewith. The first bank layer 132a having the first patterned area 136a defined therein may be disposed on the circuit area insulating layer 112 on the substrate 100 of the first sub-pixel SP1 so as to cover each of both opposing side ends of the first electrode 131 of the first sub-pixel SP1. The first bank layer 132a and a stack of the first insulating layer 125a and the second insulating layer 125b may be disposed in the same layer. The first individual light-emitting element layer 133a may be disposed in the first patterned area 136a.

According to the fifth embodiment, when the display panel 10 lacks a red light emission ability, the first individual light-emitting element layer 133a is additionally disposed in the first sub-pixel SP1 to emit red light, thereby improving the luminance of red light to balance luminance of the red, green, and blue light of the display panel 10.

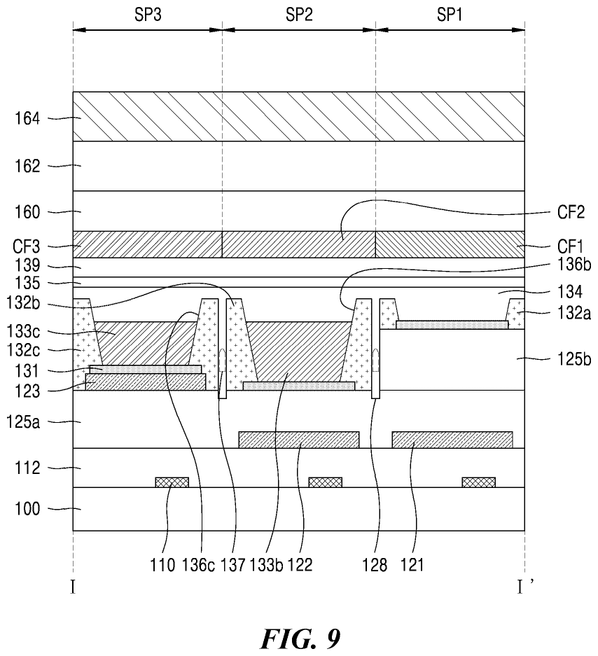

Referring to FIG. 9, in the display panel 10 according to the sixth embodiment, the individual light-emitting element layer EL2 may include the second individual light-emitting element layer 133b and the third individual light-emitting element layer 133c which are respectively disposed in the second sub-pixel SP2 and the third sub-pixel SP3 and have different vertical heights from each other. In this case, a separate light emission layer may not be disposed in the first sub-pixel SP1.

Therefore, in the first sub-pixel SP1, the first reflective electrode 121 may be disposed on the circuit area insulating layer 112, the first insulating layer 125a and the second insulating layer 125b may be sequentially stacked on the first reflective electrode 121, and the first electrode 131 may be disposed on the second insulating layer 125b. Therefore, in the first sub-pixel SP1, the first insulating layer 125a and the second insulating layer 125b may be disposed between the first reflective electrode 121 and the first electrode 131.

In the second sub-pixel SP2, the second reflective electrode 122 may be disposed on the circuit area insulating layer 112, the first insulating layer 125a may be disposed on the second reflective electrode 122, and the first electrode 131 may be disposed on the first insulating layer 125a. The second bank layer 132b having the second patterned area 136b defined therein may be disposed on the first insulating layer 125a so as to cover each of both opposing side ends of the first electrode 131. The second individual light-emitting element layer 133b may be disposed in the second patterned area 136b. Therefore, in the second sub-pixel SP2, the first insulating layer 125a may be disposed between the second reflective electrode 122 and the first electrode 131.

In the third sub-pixel SP3, the first insulating layer 125a may be formed on the circuit area insulating layer 112, the third reflective electrode 123 may be disposed on the first insulating layer 125a, and the first electrode 131 may be disposed on the third reflective electrode 123 to be in contact therewith. The third bank layer 132c having the third patterned area 136c defined therein may be disposed on the first insulating layer 125a so as to cover each of both opposing side ends of the first electrode 131. The third individual light-emitting element layer 133c may be disposed in the third patterned area 136c.

According to the sixth embodiment, when the display panel 10 lacks the green and blue light emission ability, the second individual light-emitting element layer 133b and the third individual light-emitting element layer 133c are additionally disposed in the second sub-pixel SP2 and the third sub-pixel SP3, respectively, which emit the green and blue light, respectively, thereby improving the luminance of the green and blue light to balance luminance of the red, green, and blue light of the display panel 10.

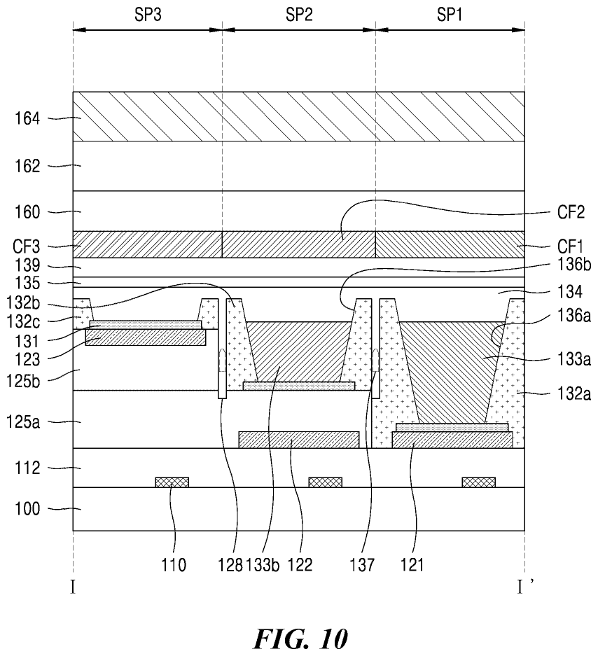

Referring to FIG. 10, in the display panel 10 according to the seventh embodiment, the individual light-emitting element layer may include the first individual light-emitting element layer 133a and the second individual light-emitting element layer 133b respectively disposed in the first sub-pixel SP1 and the second sub-pixel SP2 and having different vertical heights. In this case, a separate light emission layer may not be disposed in the third sub-pixel SP3.

Therefore, in the third sub-pixel SP3, the first insulating layer 125a and the second insulating layer 125b may be sequentially stacked on the circuit area insulating layer 112. The third reflective electrode 123 may be disposed on the second insulating layer 125b. The first electrode 131 may be disposed on the third reflective electrode 123 to be in contact therewith. The third bank layer 132c may be disposed on the second insulating layer 125b so as to cover each of both opposing side ends of the first electrode 131.

In the second sub-pixel SP2, the second reflective electrode 122 may be disposed on the circuit area insulating layer 112, the first insulating layer 125a may be disposed on the second reflective electrode 122, and the first electrode 131 may be disposed on the first insulating layer 125a. The second bank layer 132b having the second patterned area 136b defined therein may be disposed on the first insulating layer 125a so as to cover each of both opposing side ends of the first electrode 131. The second individual light-emitting element layer 133b may be disposed in the second patterned area 136b. Therefore, in the second sub-pixel SP2, the first insulating layer 125a may be disposed between the second reflective electrode 122 and the first electrode 131.

In the first sub-pixel SP1, the first reflective electrode 121 may be disposed on the circuit area insulating layer 112, and the first electrode 131 may be disposed on the first reflective electrode 121 so as to contact the first reflective electrode 121. The first bank layer 132a having the first patterned area 136a defined therein may be disposed on the circuit area insulating layer 112 so as to cover each of both opposing side ends of the first electrode 131. The first individual light-emitting element layer 133a may be disposed in the first patterned area 136a. Accordingly, the first bank layer 132a may be disposed in the same layer as a layer of the stack of the first insulating layer 125a and the second insulating layer 125b on the circuit area insulating layer 112.

According to the seventh embodiment, when the display panel 10 lacks the red and green light emission ability, the first individual light-emitting element layer 133a and the second individual light-emitting element layer 133b are additionally disposed in the first sub-pixel SP1 and the second sub-pixel SP2, respectively, which emit red and green light, thereby improving the luminance of red and green light to balance luminance of the red, green, and blue light of the display panel 10.

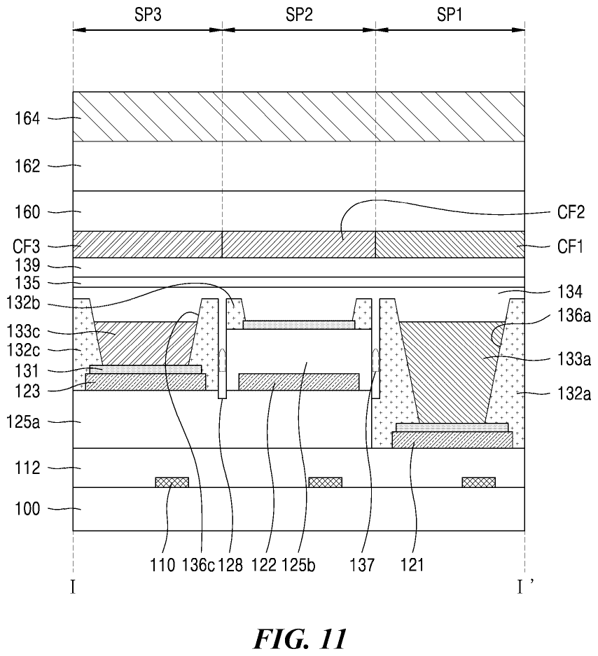

Referring to FIG. 11, in the display panel 10 according to the eighth embodiment, the individual light-emitting element layer EL1 may include the first individual light-emitting element layer 133a and the third individual light-emitting element layer 133c, which are respectively disposed in the first sub-pixel SP1 and the third sub-pixel SP3, and have different vertical heights. In this case, a separate light emission layer may not be disposed in the second sub-pixel SP2.

Therefore, in the second sub-pixel SP2, the first insulating layer 125a may be formed on the circuit area insulating layer 112. The second reflective electrode 122 may be disposed on the first insulating layer 125a, and the second insulating layer 125b may be disposed on the first insulating layer 125a and the second reflective electrode 122. The first electrode 131 may be disposed on the second insulating layer 125b. The second bank layer 132b may be disposed on the second insulating layer 125b so as to cover each of both opposing side ends of the first electrode 131. Therefore, in the second sub-pixel SP2, the second insulating layer 125b may be disposed between the second reflective electrode 122 and the first electrode 131.

In the first sub-pixel SP1, the first reflective electrode 121 may be disposed on the circuit area insulating layer 112, and the first electrode 131 may be disposed on the first reflective electrode 121 to be in contact therewith. The first bank layer 132a having the first patterned area 136a defined therein may be disposed on the circuit area insulating layer 112 so as to cover each of both opposing side ends of the first electrode 131. The first individual light-emitting element layer 133a may be disposed in the first patterned area 136a. Accordingly, the first bank layer 132a may be disposed in the same layer as a layer of the stack of the first insulating layer 125a and the second insulating layer 125b on the circuit area insulating layer insulating layer 112.

In the third sub-pixel SP3, the first insulating layer 125a may be formed on the circuit area insulating layer 112, the third reflective electrode 123 may be disposed on the first insulating layer 125a. The first electrode 131 may be disposed on the third reflective electrode 123 to be in contact therewith. The third bank layer 132c having the third patterned area 136c defined therein may be disposed on the first insulating layer 125a so as to cover each of both opposing side ends of the first electrode 131. The third individual light-emitting element layer 133c may be disposed in the third patterned area 136c.

According to the eighth embodiment, when the display panel 10 lacks the red and blue light emission ability, the first individual light-emitting element layer 133a and the third individual light-emitting element layer 133c are additionally disposed in the first sub-pixel SP1 and the third sub-pixel SP3, respectively, which emit red and blue light, thereby improving the luminance of red and blue light to balance luminance of the red, green, and blue light of the display panel 10.

As described above, the specification teaches a display panel in which at least one sub pixel includes both an individual light emitting element layer over its first electrode and a common light emitting layer spanning all sub pixels, capped by a common second electrode. The individual layers in the red, green, and blue sub pixels are formed with different vertical heights, and the reflective to second electrode distances are set in a defined order with red largest and blue smallest. These structural differences adjust the optical path length for each color, improving luminance and efficiency in targeted sub pixels without increasing overall panel thickness.

Supporting structures include patterned bank layers of different depths, sometimes coplanar with insulating layers, to position the individual layers so that their upper surfaces are level across colors despite varying heights. The specification further discloses selective use or omission of insulating layers per color to adjust optical distance and manage stack thickness, as well as targeted deployment of the individual layer only in channels with luminance shortfall. In common layer arrangements, a void within a trench filling layer interrupts lateral charge generation layer paths, reducing leakage between sub pixels.

The disclosed architecture addresses reflection efficiency and luminance imbalance while offering manufacturing advantages. By selectively removing insulating layers, the design limits thickness growth, improves uniformity, and reduces via count, which can increase aperture ratio. The result, according to the specification, is improved luminance and efficiency while maintaining structural uniformity and compatibility with existing deposition processes.

Further embodiments of the present disclosure are described below.

According to the above-described embodiment of the present disclosure, the respective distances between the reflective electrodes and the first electrodes respectively disposed in the plurality of sub-pixels may be set to be different from each other. In this case, since the insulating layer is disposed between the reflective electrode and the first electrode, the respective distances between the reflective electrodes and the first electrodes respectively disposed in the plurality of sub-pixels may be set to be different from each other. In one example, the respective distances between the reflective electrodes and the first electrodes respectively disposed in two of the plurality of sub-pixels may be equal to each other, and the vertical heights of individual light-emitting element layers respectively disposed in the two of the plurality of sub-pixels in which the respective distances between the reflective electrodes and the first electrodes are equal to each other may be set to be different from each other. Alternatively, the respective distances between the reflective electrodes and the first electrodes respectively disposed in the plurality of sub-pixels may be equal to each other, and the individual light-emitting element layer having a predetermined vertical height may be disposed in one of the sub-pixels, while the individual light-emitting element layer may not be disposed in each of the other sub-pixels. Therefore, there is no individual light-emitting element layer having the vertical height to which the vertical height of the individual light-emitting element layer disposed in one sub-pixel is compared.

Therefore, according to an embodiment of the present disclosure, the respective distances between the reflective electrodes and the first electrodes respectively disposed in the plurality of sub-pixels may be set to be different from each other and/or the vertical heights of the individual light-emitting element layers respectively disposed in the plurality of sub-pixels may be different from each other. In this case, the meaning that the vertical heights of the individual light-emitting element layers respectively disposed in the plurality of sub-pixels are different from each other may be interpreted to include a case in which a sub-pixel without the individual light-emitting element layer and a sub-pixel with the individual light-emitting element layer are compared with each other.

According to the embodiment of the present disclosure as described above, the individual light-emitting element layer may be additionally disposed selectively in each of the sub-pixels. Thus, the optimized structure suitable for each color is provided in consideration of the light-emitting characteristics of each sub-pixel such as spectrum, light extraction efficiency, and lifespan, thereby achieving balance of the red, green, and blue light emissions and high-quality image implementation.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display panel comprising:
a substrate including first to third sub-pixel areas that correspond respectively to a first sub-pixel, a second sub-pixel, and a third sub-pixel;
a reflective electrode disposed in each of the first sub-pixel, the second sub-pixel, and the third sub-pixel;
a first electrode individually disposed on each of the reflective electrodes;
an individual light-emitting element layer individually disposed on each of the first electrodes;
a common light-emitting element layer disposed on the individual light-emitting element layer and extending across the first to third sub-pixels; and
a second electrode disposed on the common light-emitting element layer.

2. The display panel of claim 1, wherein the individual light-emitting element layer includes a first individual light-emitting element layer, a second individual light-emitting element layer, and a third individual light-emitting element layer respectively disposed in the first sub-pixel, the second sub-pixel, and the third sub-pixel, and
wherein the first individual light-emitting element layer, the second individual light-emitting element layer, and the third individual light-emitting element layer have different vertical heights.

3. The display panel of claim 2, wherein the vertical height of the first individual light-emitting layer is greater than the vertical height of each of the second individual light-emitting layer and the third individual light-emitting layer, and
wherein the vertical height of the second individual light-emitting layer is greater than the vertical height of the third individual light-emitting layer.

4. The display panel of claim 2, wherein the display panel further comprises a first insulating layer disposed between the reflective electrode of the third sub-pixel and the substrate, and
wherein the first insulating layer is disposed between the reflective electrode and the first electrode in the second sub-pixel, and is not disposed in the first sub-pixel.

5. The display panel of claim 2, wherein a distance between the reflective electrode and the second electrode in the third sub-pixel is smaller than both a distance between the reflective electrode and the second electrode in the first sub-pixel and a distance between the reflective electrode and the second electrode in the second sub-pixel.

6. The display panel of claim 2, wherein the reflective electrode and the first electrode in the first sub-pixel contact each other,
wherein the reflective electrode and the first electrode in the third sub-pixel contact each other,
wherein a first insulating layer is disposed between the reflective electrode and the first electrode in the second sub-pixel.

7. The display panel of claim 2, wherein the display panel further comprises:
a first bank layer having a first patterned area defined therein, wherein the first individual light-emitting element layer is disposed in the first patterned area;
a second bank layer having a second patterned area defined therein, wherein the second individual light-emitting element layer is disposed in the second patterned area; and
a third bank layer having a third patterned area defined therein, wherein the third individual light-emitting element layer is disposed in the third patterned area,
wherein a depth of the first patterned area is greater than both a depth of the second patterned area and a depth of the third patterned area.

8. The display panel of claim 7, wherein the display panel further comprises a first insulating layer disposed under the second bank layer and the third bank layer, and
wherein the first bank layer and the first insulating layer are disposed in the same layer.

9. The display panel of claim 1, wherein the individual light-emitting element layer includes a third individual light-emitting element layer disposed in the third sub-pixel,
wherein a first insulating layer is disposed between the first electrode in each of the first to third sub-pixels and the substrate,
wherein a second insulating layer is disposed between the first electrode and the first insulating layer in the first sub-pixel, and
wherein the second insulating layer is disposed between the first electrode and the reflective electrode in the second sub-pixel.

10. The display panel of claim 1, wherein the individual light-emitting element layer includes a second individual light-emitting element layer disposed in the second sub-pixel,
wherein a first insulating layer is disposed between the first electrode in each of the first to third sub-pixels and the substrate,
wherein a second insulating layer is disposed between the first electrode and the first insulating layer in the first sub-pixel, and
wherein the second insulating layer is disposed between the first insulating layer and the reflective electrode in the third sub-pixel.

11. The display panel of claim 1, wherein the individual light-emitting element layer includes a first individual light-emitting element layer disposed in the first sub-pixel,
wherein a first insulating layer is disposed between the substrate and the first electrode in each of the second sub-pixel and the third sub-pixel,
wherein a second insulating layer is disposed between the reflective electrode and the first electrode in the second sub-pixel, and
wherein the second insulating layer is disposed between the first insulating layer and the reflective electrode in the third sub-pixel.

12. The display panel of claim 1, wherein the individual light-emitting element layer includes a second individual light-emitting element layer and a third individual light-emitting element layer respectively disposed in the second sub-pixel and the third sub-pixel and having different vertical heights,
wherein a first insulating layer is disposed between the first electrode in each of the first to third sub-pixels and the substrate, and
wherein a second insulating layer is disposed between the first electrode and the first insulating layer in the first sub-pixel.

13. The display panel of claim 1, wherein the individual light-emitting element layer includes a first individual light-emitting element layer and a second individual light-emitting element layer respectively disposed in the first sub-pixel and the second sub-pixel and having different vertical heights,
wherein a first insulating layer is disposed between the substrate and the first electrode in each of the second sub-pixel and the third sub-pixel, and
wherein a second insulating layer is disposed between the reflective electrode and the first insulating layer in the third sub-pixel.

14. The display panel of claim 1, wherein the individual light-emitting element layer includes a first individual light-emitting element layer and a third individual light-emitting element layer respectively disposed in the first sub-pixel and the third sub-pixel and having different vertical heights,
wherein a first insulating layer is disposed between the substrate and the first electrode in each of the second sub-pixel and the third sub-pixel, and
wherein a second insulating layer is disposed between the first electrode and the reflective electrode in the second sub-pixel.

15. A display device comprising:
a substrate including a plurality of sub-pixel areas that correspond respectively to a plurality of sub-pixels;
a reflective electrode individually disposed in each of the plurality of sub-pixels;
a first electrode individually disposed on each of the reflective electrodes and individually disposed in each of the plurality of sub-pixels;
an individual light-emitting element layer disposed on each of at least one first electrode;
a common light-emitting element layer disposed on the first electrodes and disposed in the plurality of sub-pixels; and
a second electrode disposed on the common light-emitting element layer and disposed in the plurality of sub-pixels,
wherein respective distances between the reflective electrodes and the first electrodes respectively disposed in the plurality of sub-pixels are different from each other.

16. The display device of claim 15, wherein vertical heights of the individual light-emitting element layers respectively disposed in the plurality of sub-pixels are different from each other.

17. The display device of claim 15, wherein the plurality of sub-pixels includes a first sub-pixel configured to emit short wavelength light, a second sub-pixel configured to emit medium wavelength light, and a third sub-pixel configured to emit long wavelength light, and
wherein the respective distances between the reflective electrodes and the second electrodes increase in order from the short wavelength sub-pixel to the medium wavelength sub-pixel to the long wavelength sub-pixel.

18. The display device of claim 15, wherein the common light-emitting element layer is present in a trench between adjacent sub-pixels, and
wherein a void is formed within the common light-emitting element layer to interrupt a lateral charge generation layer path between the adjacent sub-pixels.

19. A display panel comprising:
a substrate including a plurality of sub-pixel areas corresponding to a plurality of sub-pixels;
a reflective electrode individually disposed in each of the plurality of sub-pixels;
a first electrode individually disposed on each of the reflective electrodes and individually disposed in each of the plurality of sub-pixels;
a common light-emitting element layer disposed on the first electrodes and disposed in the plurality of sub-pixels; and
a second electrode disposed on the common light-emitting element layer and disposed in the plurality of sub-pixels,
wherein respective distances between the reflective electrodes and the first electrodes respectively disposed in the plurality of sub-pixels are different from each other.
